(19) United States
(12) Patent Application Publication
(10) Pub. No.: US 2013/0126692 A1
(43) Pub. Date: May 23, 2013

(54) BASE FOR HARD DISK DRIVE AND HARD DISK DRIVE INCLUDING THE SAME

(71) Applicant: Il Geun JEON, Hwaseong (JP)

(72) Inventor: Il Geun JEON, Hwaseong (JP)

(73) Assignee: SAMSUNG ELECTRO-MECHANICS CO., LTD., Suwon-si (JP)

(21) Appl. No.: 13/358,127

(22) Filed: Jan. 25, 2012

(30) Foreign Application Priority Data
Nov. 17, 2011 (KR) 10-2011-0120236

(51) Int. Cl. H05K 7/00; B21J 5/12; B23P 15/00; B23P 11/02; G11B 21/02; B23P 11/00

(52) U.S. Cl. 248/346.01; 360/75; 29/428; 29/525; 29/456; 72/379.2; G9B/21.003

(57) ABSTRACT

There is provided a base for a hard disk drive formed by press processing, the base including: coupling parts corresponding to coupling units to be coupled to components for operating the hard disk drive and formed by depressing a predetermined region of one surface of the base to thereby protrude the predetermined region outward from the other surface thereof, wherein the coupling parts are closed by a cap member.

### CROSS-REFERENCE TO RELATED APPLICATIONS

This application claims the priority of Korean Patent Application No. 10-2011-0120236 filed on Nov. 17, 2011, in the Korean Intellectual Property Office, the disclosure of which is incorporated herein by reference.

### BACKGROUND OF THE INVENTION

1. Field of the Invention

The present invention relates to a base for a hard disk drive and a hard disk drive including the same, and more particularly, to a base for a hard disk drive having an improved coupling structure between the base and a component, and a hard disk drive including the same.

2. Description of the Related Art

A hard disk drive (HDD), an information storage device provided in a computer, reads data stored on a disk or writes data to a disk using a magnetic head.

In a hard disk drive, a base is installed with a head driver, that is, a head stack assembly (HSA), capable of altering a position of the magnetic head with respect to the disk. The magnetic head performs its function while moving to a desired position in a state in which it is suspended above a writing surface of the disk by the head driver at a predetermined height.

According to the related art, in manufacturing a base provided in the hard disk drive, a post-processing scheme of die-casting aluminum (Al) and then removing burring, or the like, generated due to the die-casting process, has been used.

However, in the die-casting scheme according to the related art, since a casting process of injecting molten aluminum (Al) into a mold to form a base is performed, high temperatures and pressures are required, such that a large amount of energy is required in the process and a process time is increased.

Further, in terms of a lifespan of a die-casting mold, there is a limitation in manufacturing a large number of bases using a single mold, and a base manufactured by the die-casting process may have poor dimensional precision.

Therefore, in order to solve defects in the die-casting process, the base has been manufactured using a pressing process. However, in the case of manufacturing the base by the press process, the base is limited to having a uniform thickness, due to a process of pressing and bending a plate.

Therefore, in the case of coupling components for driving the hard disk drive to the base manufactured by the press process, a defect may occur in implementing coupling parts. In addition, even in the case that coupling parts are implemented, complete sealing of an inner portion of the hard disk drive should not be affected by the coupling parts.

In addition, in a case in which a plurality of coupling parts are formed to be adjacent to each other in order to be coupled to components for driving the hard disk drive, it is very difficult to form the plurality of coupling parts as described above in the base manufactured by the press process.

Therefore, research into a technology of manufacturing a further improved hard disk drive by solving a limitation that a base is limited to having a uniform thickness, even in the case of manufacturing the base by a press processing, has been urgently demanded.

### SUMMARY OF THE INVENTION

An aspect of the present invention provides a base for a hard disk drive having improved performance and an improved lifespan through a completely sealed inner portion thereof, together with facilitating coupling between a base manufactured by press processing and components for driving the hard disk drive, and a hard disk drive including the same.

According to an aspect of the present invention, there is provided a base for a hard disk drive formed by press processing, the base including: coupling parts corresponding to coupling units to be coupled to components for operating the hard disk drive and formed by depressing a predetermined region of one surface of the base to thereby protrude the predetermined region outward from the other surface thereof, wherein the coupling parts are closed by a cap member.

The coupling part may be in communication with the exterior, and the cap member may be inserted into an outer surface of the coupling part protruded toward the other surface to thereby close the coupling part.

The cap member may be press-fitted onto the outer surface of the coupling part protruded toward the other surface to thereby close the coupling part.

The cap member may be formed of a metallic material or a rubber material.

The coupling unit may be press-fitted onto and fixed to the coupling part.

The coupling unit may be a screw to be attached to the coupling part.

According to another aspect of the present invention, there is provided a base for a hard disk drive formed by press processing, the base including: coupling parts corresponding to coupling units to be coupled to components for operating the hard disk drive and formed by depressing a predetermined region of one surface of the base to thereby protrude the predetermined region outward from the other surface thereof in a state in which it is closed.

The coupling unit may be a screw to be attached to the coupling part.

According to another aspect of the present invention, there is provided a hard disk drive including: the base for a hard disk drive as described above; a spindle motor coupled to the base to thereby rotate a disk; and a head driver moving a magnetic head to a predetermined position with regard to the disk, the magnetic head writing data to the disk and reproducing the data written on the disk.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic exploded perspective view showing a hard disk drive including a base for a hard disk drive according to an embodiment of the present invention;

FIG. 2 is a schematic perspective view showing a state after a lower yoke is coupled to the base for a hard disk drive according to the embodiment of the present invention;

FIG. 3 is a schematic enlarged cross-sectional view of part A of FIG. 2;

FIGS. 4 through 6 are, respectively, schematic perspective views and schematic cross-sectional views showing a process of coupling the lower yoke to the base for a hard disk drive according to the embodiment of the present invention (only part X of FIG. 1 is shown); and

FIG. 7 is a schematic perspective view and a schematic cross-sectional view showing a state after a lower yoke is coupled to a base for a hard disk drive according to another embodiment of the present invention.

### DETAILED DESCRIPTION OF THE INVENTION

Embodiments of the present invention will now be described in detail with reference to the accompanying drawings. However, it should be noted that the spirit of the present invention is not limited to the embodiments set forth herein and those skilled in the art and understanding the present invention can easily accomplish retrogressive inventions or other embodiments included in the spirit of the present invention by the addition, modification, and removal of components within the same spirit, but those are construed as being included in the spirit of the present invention.

Further, like reference numerals will be used to designate like components having similar functions throughout the drawings within the scope of the present invention.

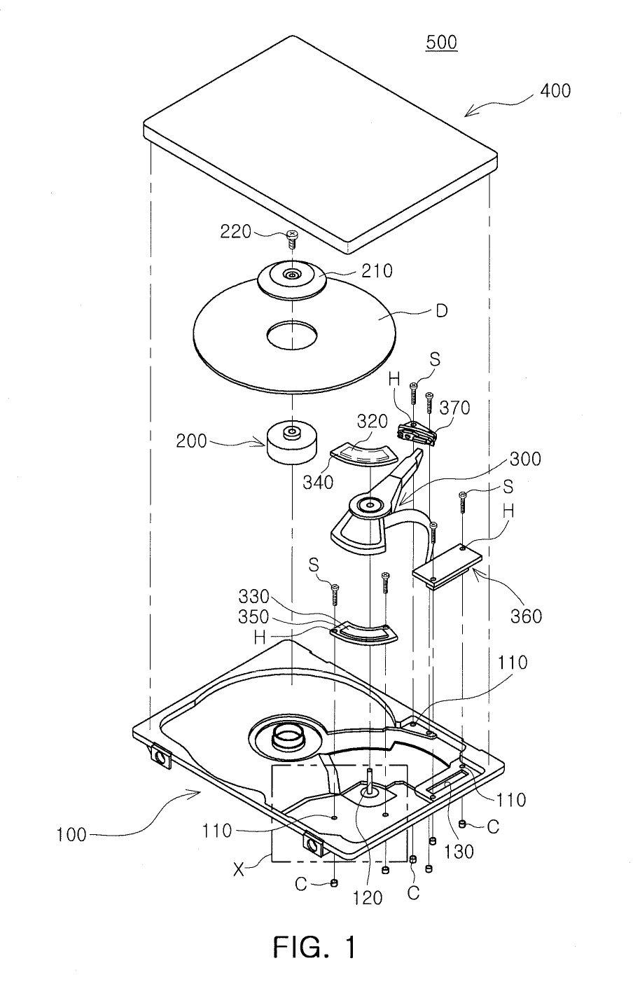

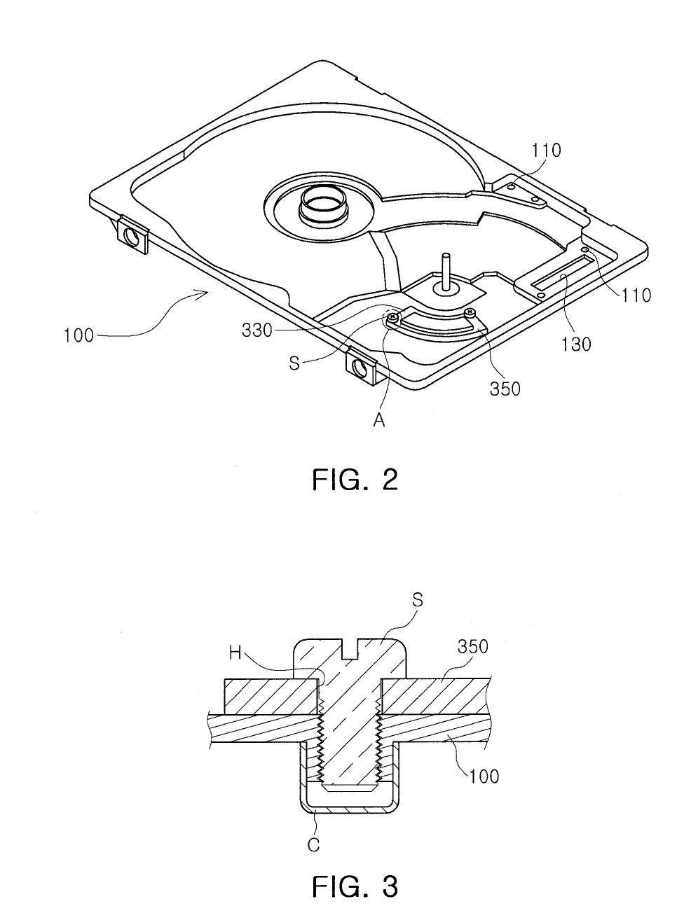

FIG. 1 is a schematic exploded perspective view showing a hard disk drive including a base for a hard disk drive according to an embodiment of the present invention; FIG. 2 is a schematic perspective view showing a state after a lower yoke is coupled to the base for a hard disk drive according to the embodiment of the present invention; and FIG. 3 is a schematic enlarged cross-sectional view of part A of FIG. 2.

Referring to FIGS. 1 through 3, the hard disk drive 500 may include a base 100 for a hard disk drive (hereinafter, referred to as a base), a spindle motor 200 disposed in an internal space provided by the base 100, and a head driver 300.

The base 100 may indicate a housing forming an appearance together with the cover 400 in the hard disk drive 500 according to the embodiment of the present invention and include at least one coupling part 110.

Here, the base 100 may be manufactured to have a basic shape by a press processing and be then manufactured to have a final shape by bending or cutting, which is additional processing.

That is, the base 100 according to the embodiment of the present invention may be manufactured by performing a single process such as press processing or an additional process on a cold rolled steel sheet (SPCC, SPCE, or the like), a hot rolled steel sheet, a stainless steel, a lightweight alloy steel sheet such as a boron or magnesium alloy, unlike the post-processing scheme according to the related art in which aluminum (Al) is die-cast and a burr, or the like, generated due to the die-casting is then removed.

Therefore, since the base 100 according to the embodiment of the present invention may be manufactured by the press processing, a process time and energy consumption may be significantly reduced, whereby production capability may be improved.

Here, the base 100 may provide an internal space, wherein the internal space indicates a space in which the spindle motor 200 and the head driver 300 are disposed.

Meanwhile, the base 100 may include at least one coupling part 110 formed therein in order to be coupled to components for operating the hard disk drive 500 according to the embodiment of the present invention, for example, a lower yoke 350 having a lower magnet 330 coupled thereto, a flexible printed circuit assembly (FPCA) 360 electrically connected to a main circuit board (not shown) for controlling an operation of the head drive 300, a ramp 370, or the like.

The coupling part 110 may be formed by depressing a predetermined region of one surface of the base 100 to thereby protrude the predetermined region outward from the other surface thereof by a burring process and indicates a hole that is in communication with the exterior.

That is, the coupling par 110 may be formed by protruding a predetermined region of an upper surface of the base 100 toward a lower surface thereof by the burring process. A detailed description of the coupling part 110 will be provided while describing components configuring the hard disk drive 500 according to the embodiment of the present invention.

The spindle motor 200, which is to rotate the disk D, may be fixedly mounted at an approximately central portion of the base 100.

The disk D, coupled to the spindle motor 200 to thereby rotate together with the spindle motor 200, may have a writing surface on which data is written.

Here, the spindle motor 200 may include a clamp 210 coupled to an upper end portion thereof by a screw 220 in order to firmly fix the disk D thereto.

In addition, although FIG. 1 shows a configuration in which a single disk D is mounted on the spindle motor 200, this configuration is only an example. That is, one or more disk D may be mounted on the spindle motor 200. In the case in which a plurality of disks D are mounted as described above, a ring shaped spacer for maintaining an interval between the disks D may be disposed between the disks D.

The head driver 300 is called a head stack assembly (HAS) and may be a component having a magnetic head mounted thereon and moving the magnetic head to a predetermined position to thereby write the data to the disk D or read the data written on the disk D.

In addition, the head driver 300 may move the magnetic head to a predetermined position of the disk D by a voice coil motor (VCM) including a coil 310 and upper and lower magnets 320 and 330.

The VCM may be controlled by a servo control system and rotate the magnetic head around a pivot axis 120 in a direction according to the Fleming's left hand rule by interaction between current input by the coil 310 provided in the VCM and magnetic fields formed by the upper and lower magnets 320 and 330.

Here, each of the upper and lower magnets 320 and 330 disposed on each of upper and lower portions of the coil 310 provided in the VCM may be respectively coupled to upper and lower yokes 340 and 350 in order to increase magnetic flux density and be fixed to the base 100.

That is, each of the upper and lower magnets 320 and 330 may be fixed to the base 110 via the upper and lower yokes 340 and 350, and at least one of the upper and lower yokes 340 and 350 may include a coupling hole H formed therein in order to be coupled to the base 100.

Here, although the coupling hole formed in the upper yoke 340 is not shown in FIG. 1, it may have the same configuration as that of the coupling hole H formed in the lower yoke 350.

The coupling hole H formed in the lower yoke 350 may be formed to correspond to the coupling part 110 formed in the base 100. More specifically, the coupling hole H may be in communication with the coupling part 110.

The coupling hole H and the coupling part 110 may have a separate coupling unit S inserted thereinto, and the lower yoke 350 and the base 100 may be stably coupled to each other by the coupling unit S.

Here, the coupling unit S may be inserted into at least one of the coupling hole H and the coupling part 110 by a press-fitting scheme.

Here, the coupling unit S may be a screw attached to the coupling hole H and the coupling part 110.

In the case in which the coupling unit S is the screw, at least one of a sidewall of the coupling hole H and a side wall of the coupling part 110 may include a screw tap formed therein in order to be attached to the screw simultaneously with a burring process for forming the coupling part 110 or through a separate process after the burring process.

Meanwhile, even in the case in which the base 100 and the lower yoke 350 may be firmly coupled to each other by the coupling unit S inserted into the coupling hole H and the coupling part 110, the coupling part 110 and the coupling unit S or the coupling hole H and the coupling unit S may have a fine space formed therebetween.

This fine space may become a movement path through which fine foreign materials are introduced into the hard disk drive 500 according to the embodiment of the present invention, and the fine foreign materials introduced into the hard disk drive 500 may pollute the disk D and the magnetic head.

Therefore, in order to improve performance of the hard disk drive 500 according to the embodiment of the present invention, the fine space as described above needs to be completely blocked from the exterior. To this end, the coupling part 110 protruded toward the lower surface of the base 100, which is the other surface of the base 100, may include a cap member C coupled to an outer surface thereof.

The cap member C may be press-fitted onto and fixed to the outer surface of the coupling part 110 protruded toward the lower surface of the base 100, which is the other surface of the base 100, and be formed of a metallic material or a rubber material having elasticity.

Therefore, since the coupling part 110 formed by the burring process may be completely blocked from the exterior by the cap member C, the introduction of the fine foreign materials may be prevented even after the lower yoke 350 is coupled to the base 100 using the coupling unit S.

Here, the same scheme as the scheme of fixing the lower yoke 350 having the lower magnet 330 coupled thereto to the base 100 by the coupling unit S as described above may be applied to the upper yoke 340 having the upper magnet 320 coupled thereto.

Meanwhile, when an operation start command is input to the hard disk drive 500 according to the embodiment of the present invention, the disk D may start to rotate, and the VCM rotates a swing arm in a counterclockwise direction and may move the magnetic head onto the writing surface of the disk D.

On the other hand, when an operation stop command is input to the hard disk drive 500 according to the embodiment of the present invention, the VCM may rotate the swing arm in a clockwise direction to thereby allow the magnetic head to deviate from the disk D.

The magnetic head deviating from the writing surface of the disk D may be parked in the ramp 370 provided exterior the disk D.

Here, the ramp 370 may space the magnetic head from the disk D in the case in which the magnetic head moves to the disk I), simultaneously with parking the magnetic head, whereby data of the disk D may be stably read.

In addition, the ramp 370 may include at least one coupling hole H formed therein in order to be coupled to the base 100 and may be firmly fixed to the base 100 by the coupling unit S inserted into the coupling hole H and the coupling part 110 formed in the base 100.

Here, as a coupling scheme between the ramp 370 and the base 100, the same scheme as the scheme of fixing the lower yoke 350 having the lower magnet 330 coupled thereto to the base 100 by the coupling unit S as described above may be used. In addition, a fine space that may be formed between the coupling hole H of the ramp 370 and the coupling unit S or the coupling part 110 of the base 100 and the coupling unit S may be closed by the cap member C.

Meanwhile, the head driver 300 may be electrically connected to the main circuit board (not shown) disposed on the lower surface of the base 100 so as to rotate the swing arm by providing driving force to the VCM.

This may be implemented via the FPCA 360 including a connector (not shown). The connector (not shown) of the FPCA 360 may be electrically connected to the main circuit board (not shown).

Here, the base 100 may include a connector penetration part 130 formed therein in order to electrically connect the connector (not shown) to the main circuit board (not shown), wherein the connector (not shown) may penetrate through the connector penetration part 130.

In addition, the FPCA 360 may include at least one coupling hole H formed therein in order to fix the connector (not shown) penetrating through the connector penetration part 130 formed in the base 100 to the base 100.

Here, as a coupling scheme between the FPCA 360 and the base 100, the same scheme as the scheme of fixing the lower yoke 350 having the lower magnet 330 coupled thereto to the base 100 by the coupling unit S as described above may be used. In addition, a fine space that may be formed between the coupling hole H of the FPCA 360 and the coupling unit S or the coupling part 110 of the base 100 and the coupling unit S may be closed by the cap member C.

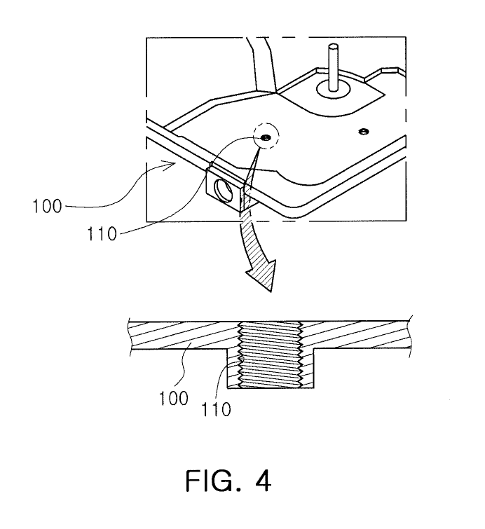

FIGS. 4 through 6 are, respectively, schematic perspective views and schematic cross-sectional views showing a process of coupling the lower yoke to the base for a hard disk drive according to the embodiment of the present invention (only part X of FIG. 1 is shown).

Referring to FIG. 4, which is a view showing a process of forming the coupling part 110 to couple the lower yoke 350 to the base 100, the coupling part 110 may be formed by pressing a predetermined region of an upper surface of the base 100.

That is, the coupling part 110 may be formed by the burring process and be formed by protruding the predetermined region of the upper surface of the base 100 toward the lower surface of the base 100 simultaneously with depressing the predetermined region.

Here, the coupling part 110 may include the screw tap formed therein in order to be attached to the coupling unit S, which is the screw, simultaneously with the burring process or through a separate process after the burring process.

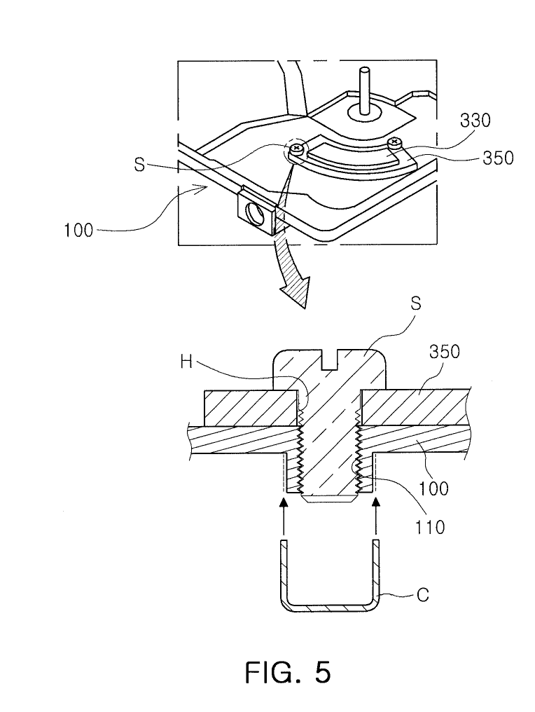

Referring to FIG. 5, after the coupling part 110 to be coupled to the lower yoke 350 is formed in the base 100, the lower yoke 350 may be disposed on the base 100, and the coupling part 110 and the coupling hole H formed in the lower yoke 350 may coincide with each other.

Then, the coupling unit S may be inserted into the coupling hole H and the coupling part 110 to thereby fix the lower yoke 350 to the base 100.

Here, the coupling unit S may be formed of the screw to thereby be coupled to the coupling hole H and the coupling part 110 in a screw coupling scheme or be coupled thereto in a press-fitting scheme.

Meanwhile, after the coupling unit S is coupled to the coupling part 110 and the coupling hole H, the cap member C, which is a separate member, for closing a fine space that may be formed between the coupling part 110 and the coupling unit S or between the coupling hole H and the coupling unit S may be required.

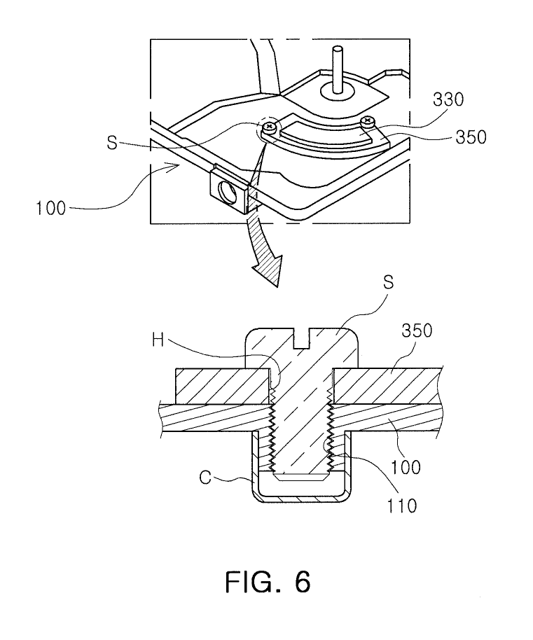

Referring to FIG. 6, the cap member C for closing a fine space that may be formed between the coupling part 110 and the coupling unit S or between the coupling hole H and the coupling unit S may be coupled to the outer surface of the coupling part 110.

The cap member C may be press-fitted onto and fixed to the outer surface of the coupling part 110 protruded toward the lower surface of the base 100, which is the other surface of the base 100, and be formed of a metallic material or a rubber material having elasticity.

Therefore, since the coupling part 110 formed by the burring process may be completely blocked from the exterior by the cap member C, the introduction of the fine foreign materials may be prevented even after the lower yoke 350 is coupled to the base 100 using the coupling unit S.

Additionally, although a coupling scheme between the lower yoke 350 and the base 100 using the coupling unit S has been described with reference to FIGS. 4 through 6, the above-mentioned coupling scheme is not limited thereto, but may be applied to all of the components for operating the hard disk drive 500 according to the embodiment of the present invention including the ramp 370 or the FPCA 360 described above.

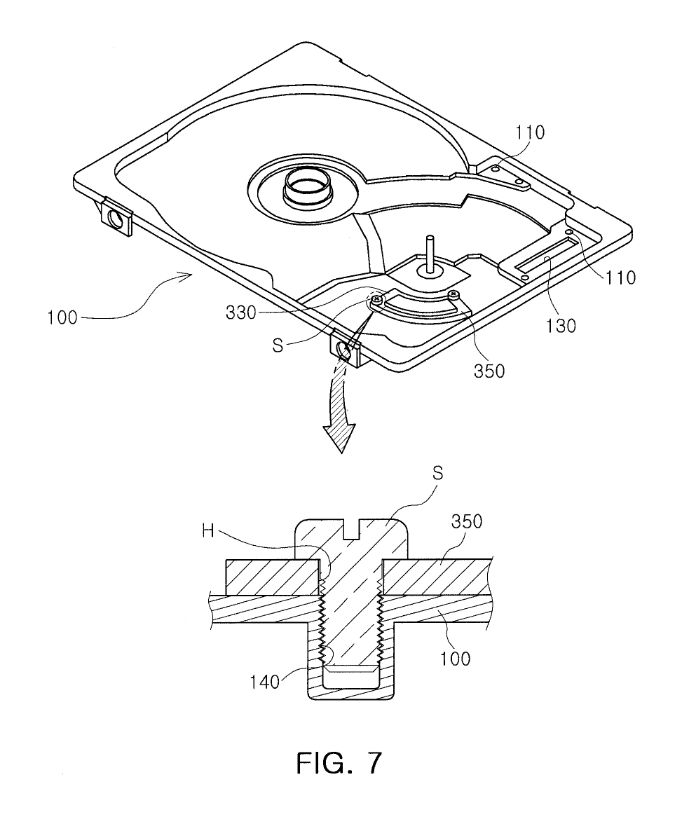

FIG. 7 is a schematic perspective view and a schematic cross-sectional view showing a state after a lower yoke is coupled to a base for a hard disk drive according to another embodiment of the present invention.

Referring to FIG. 7, a base 100 may include at least one coupling part 140 formed therein in order to be coupled to a lower yoke 350.

The coupling part 140 may be formed by depressing a predetermined region of one surface of the base 100 to thereby protrude the predetermined region outward from the other surface thereof in a state in which it is closed.

In other words, the predetermined region of the upper surface of the base 100 may be pressed to thereby be depressed.

Therefore, the coupling part 140 may be a groove protruded toward the lower surface of the base 100 in a state in which it is closed.

Here, the lower yoke 350 may be firmly fixed to the base 100 by allowing the coupling part 140 having a groove shape and a coupling hole H formed in the lower yoke 350 to coincide with each other and then performing the screwing by a coupling unit S formed of a screw.

In addition, the lower yoke 350 may also be firmly fixed to the base 100 by press-fitting the coupling unit S into the coupling part 140 and the coupling hole H.

Meanwhile, since the coupling part 140 formed in the base 100 may be the closed groove, even in a case in which the coupling unit S is coupled to the coupling part 140, a fine space that is in communication with the exterior may not be formed.

Therefore, the cap member C blocking the foreign materials from being introduced into the hard disk drive 500 and described with reference to FIGS. 1 through 6 may not be required.

That is, the coupling part 140 may be formed as a groove type coupling part as it is not in communication with the exterior.

Additionally, although a coupling scheme between the lower yoke 350 and the base 100 using the coupling unit S has been described with reference to FIG. 7, the above-mentioned coupling scheme is not limited thereto, but may be applied to all of the components for operating the hard disk drive 500 according to the embodiment of the present invention including the ramp 370 or the FPCA 360 described above.

As set forth above, with the base for a hard disk drive and the hard disk drive including the same according to the embodiments of the present invention, the base manufactured by the press processing and the components for driving the hard disk drive may be simply and firmly coupled to each other.

In addition, the sealing function of the hard disk drive is improved, whereby performance and a lifespan of the hard disk drive may be significantly increased.

While the present invention has been shown and described in connection with the embodiments, it will be apparent to those skilled in the art that modifications and variations can be made without departing from the spirit and scope of the invention as defined by the appended claims.

What is claimed is:

1. A base for a hard disk drive formed by press processing, the base comprising:
coupling parts corresponding to coupling units to be coupled to components for operating the hard disk drive and formed by depressing a predetermined region of one surface of the base to thereby protrude the predetermined region outward from the other surface thereof,
the coupling parts being closed by a cap member.

2. The base of claim 1, wherein the coupling part is in communication with the exterior, and
the cap member is inserted into an outer surface of the coupling part protruded toward the other surface to thereby close the coupling part.

3. The base of claim 2, wherein the cap member is press-fitted onto the outer surface of the coupling part protruded toward the other surface to thereby close the coupling part.

4. The base of claim 1, wherein the cap member is formed of a metallic material or a rubber material.

5. The base of claim 1, wherein the coupling unit is press-fitted onto and fixed to the coupling part.

6. The base of claim 1, wherein the coupling unit is a screw to be attached to the coupling part.

7. A base for a hard disk drive formed by press processing, the base comprising:
coupling parts corresponding to coupling units to be coupled to components for operating the hard disk drive and formed by depressing a predetermined region of one surface of the base to thereby protrude the predetermined region outward from the other surface thereof in a state in which it is closed.

8. The base of claim 7, wherein the coupling unit is a screw to be attached to the coupling part.

9. A hard disk drive comprising:
the base for a hard disk drive of claim 1;
a spindle motor coupled to the base to thereby rotate a disk; and
a head driver moving a magnetic head to a predetermined position with regard to the disk, the magnetic head writing data to the disk and reproducing the data written on the disk.

10. A hard disk drive comprising:
the base for a hard disk drive of claim 7;
a spindle motor coupled to the base to thereby rotate a disk; and
a head driver moving a magnetic head to a predetermined position with regard to the disk, the magnetic head writing data to the disk and reproducing the data written on the disk.
